(19) United States
(12) Patent Application Publication
(10) Pub. No.: US 2026/0144169 A1
(43) Pub. Date: May 21, 2026

(54) SEMICONDUCTOR CHIP AND SEMICONDUCTOR PACKAGE

(71) Applicant: Samsung Electronics Co., Ltd., Suwon-si (KR)

(72) Inventors: Myungjun KIM, Suwon-si (KR); Youngseok BYEON, Suwon-si (KR); Kyungseok PARK, Suwon-si (KR); Jung-June PARK, Suwon-si (KR); Jungmin SEO, Suwon-si (KR); Chiweon YOON, Suwon-si (KR)

(73) Assignee: Samsung Electronics Co., Ltd., Suwon-si (KR)

(21) Appl. No.: 19/340,278

(22) Filed: Sep. 25, 2025

(30) Foreign Application Priority Data
Nov. 15, 2024 (KR) 10-2024-0163238

(51) Int. Cl. H01L 23/00; H01L 23/31; H01L 23/498; H01L 25/065; H01L 25/18; H10B 80/00

(52) U.S. Cl. CPC H10W 90/701; H10B 80/00; H10W 70/685; H10W 74/117; H10W 90/00; H10W 72/59; H10W 72/923; H10W 72/9232; H10W 90/754; H10W 90/792

(57) ABSTRACT

A semiconductor chip and a semiconductor package are provided. The semiconductor chip includes a substrate, a wire pad on the substrate and configured to electrically connect with a first wire and a second wire separated from each other, and a support structure between the substrate and the wire pad, the support structure including a conductive metal material, a ring region along a boundary of the wire pad in a plan view, and a center region between the first and second wires in a plan view.

### CROSS-REFERENCE TO RELATED APPLICATION

This application claims priority to and the benefit of Korean Patent Application No. 10-2024-0163238 filed with the Korean Intellectual Property Office on Nov. 15, 2024, the entire contents of which are incorporated herein by reference.

### BACKGROUND

The present disclosure relates to semiconductor chips and semiconductor packages.

With the rapid development of the electronics industry and the demands of users, electronic devices are becoming increasingly smaller. To manufacture miniaturized, high-performance, and high-capacity electronic devices, a method of stacking semiconductor devices has been proposed. As examples, technologies such as System-in-Package (SiP), where heterogeneous stacked semiconductor chips operate as a single system, and Multi-Chip Package (MCP), where multiple semiconductor chips are integrated within a single semiconductor package, have been proposed. A semiconductor chip within a semiconductor package includes pads exposed to the outside for connection to the outside, and the pads may be connected to another semiconductor chip or package substrate using method such as wire bonding. Semiconductor chips can receive power necessary for operation or transmit and receive signals with other devices through wire pads. In particular, the pads that receive power are bonded with multiple wires in a parallel manner, and the semiconductor chip can improve the impedance performance through the multiple wire bonding structure, thereby improving the integrity of the power supply.

### SUMMARY

Some example embodiments provide a semiconductor chip and semiconductor package having improved power integrity performance and robustness to stress during wire bonding.

According to some example embodiments, a semiconductor chip including a substrate; a wire pad on the substrate and configured to electrically connect with a first wire and a second wire separated from each other; and a support structure between the substrate and the wire pad, the support structure including a conductive metal material, a ring region along a boundary of the wire pad in a plan view, and a center region between the first and second wires in a plan view may be provided.

According to some example embodiments, a semiconductor chip including a substrate; a first wire pad on the substrate and configured to receive a power voltage; a second wire pad non-overlapping with the first wire pad on the substrate in a plan view and configured to receive a data signal; and a support structure between the substrate and the first wire pad, the support structure including a conductive metal material, a ring region along a boundary of the first wire pad in a plan view, and a center region extending in a first direction within the ring region may be provided.

According to some example embodiments, a semiconductor package including a package substrate including a substrate wire pad; and a first semiconductor chip including a chip wire pad on the package substrate and connected to the substrate wire pad through a first and second wire, the first semiconductor chip including a support structure including a ring region along a boundary of the chip wire pad in a plan view and a center region between the first and second wires in a plan view may be provided.

According to some example embodiments, a method of manufacturing a semiconductor package including connecting two or more wires to a substrate wiring pad defined by a package substrate; and connecting the two or more wires to a chip wire pad defined by a semiconductor chip, the semiconductor chip including a substrate; a wiring layer on the substrate; the chip wire pad on the wiring layer; and a support structure electrically connecting the wiring layer to the wiring pad, the support structure including an annular shape along a boundary of the chip wire pad in a plan view, and a center region extending across the annular shape in a plan view, the center region is vertically overlapped by the chip wire pad may be provided.

### BRIEF DESCRIPTION OF THE DRAWINGS

FIG. 1 is a plan view illustrating a semiconductor package according to some example embodiments.

FIG. 2 is a cross-sectional view illustrating a section taken along line A-A′ of FIG. 1.

FIG. 3 is an enlarged view of the S1 region of FIG. 2.

FIG. 4 is a cross-sectional view illustrating a section taken along line B-B′ of FIG. 1.

FIG. 5 is an enlarged view of S2 region of FIG. 4.

FIG. 6 is an enlarged view of the PP region of FIG. 1.

FIG. 7 illustrates a support structure according to some example embodiments.

FIGS. 8 and 9 illustrate a chip wire pad and a support structure according to some example embodiments.

FIG. 10 is a cross-sectional view illustrating a semiconductor package according to some example embodiments.

FIG. 11 is an enlarged view of S3 region of FIG. 10.

FIGS. 12 and 13 illustrate a memory device to which a structure of a semiconductor chip according to some example embodiments is applied.

FIGS. 14 and 15 illustrate a memory device to which a structure of a semiconductor chip according to some example embodiments is applied.

### DETAILED DESCRIPTION

The present disclosure will be described in detail hereinafter with reference to the accompanying drawings, in which some example embodiments of the present disclosure are shown. As those skilled in the art would realize, the described example embodiments may be modified in various different ways, all without departing from the spirit or scope of the present disclosure.

The drawings and description are to be regarded as illustrative in nature and not restrictive, and like reference numerals designate like elements throughout the specification.

Additionally, the sizes and thicknesses of each component shown in the drawings are arbitrarily depicted for convenience of explanation and are not necessarily limited to the illustrated embodiments.

In addition, unless explicitly stated to the contrary, the word “comprise,” and variations such as “comprises” and “comprising,” should be understood to imply the inclusion of stated elements but not the exclusion of any other elements.

It should be further understood by those skilled in the art that if a specific number of an introduced claim recitation is intended, such an intent will be explicitly recited in the claim, and in the absence of such recitation no such intent is present.

For example, to facilitate understanding, the following appended claims may contain usage of the introductory phrases “at least one” and “one or more” to introduce claim recitations. However, the use of such phrases should not be understood as a limitation described by the unambiguous article “one,” for one example.

Furthermore, in those instances where a convention analogous to “at least one of A, B, and C, etc.” is used, in general such a construction is intended in the sense in which one having skill in the art would understand the convention (e.g., “a system having at least one of A, B, and C” would include but not be limited to systems that have A alone, B alone, C alone, A and B together, A and C together, B and C together, and/or A, B, and C together, etc.). Alternatively, a disjunctive word and/or phrase presenting two or more alternative terms, whether in the description, claims, or drawings, should be understood as likely to include one of the terms, either of the terms, or both of the terms unless context dictates otherwise. For example, the phrase “A or B” should be typically understood to include the possibilities of “A” or “B” or “A and B.”

In addition, throughout the specification, when it is said that “one component is disposed adjacent to another component,” it means that one component and another component are disposed adjacent to each other so that no component the same as or similar to one component is disposed between one component and another component, or one component and another component are in contact with each other. For example, the adjacent disposition of the same or similar “X” and “Y” includes “X” and “Y” being adjacent so that no component the same as or similar to “X” is disposed between “X” and “Y,” or “X” and “Y” are in contact with each other.

In this specification, “a module,” “a unit,” or “a part” perform at least one function or operation, and may be realized as hardware, such as a processor or integrated circuit, software that is executed by a processor, or a combination thereof.

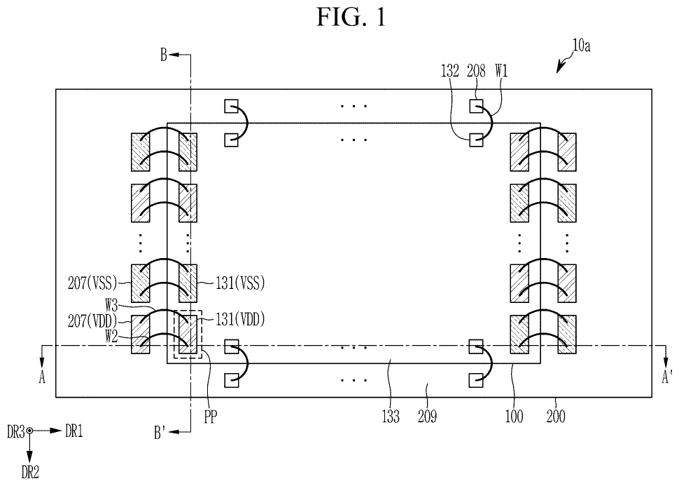

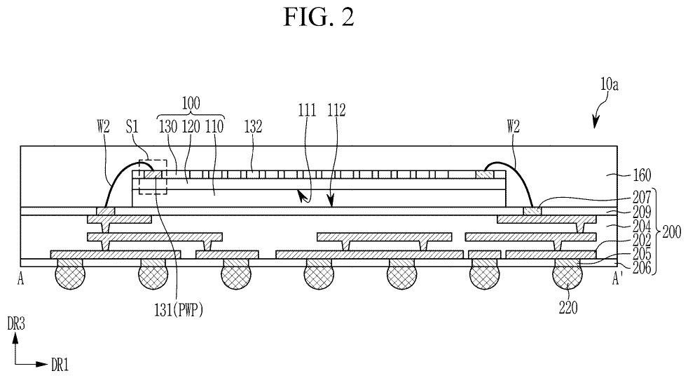

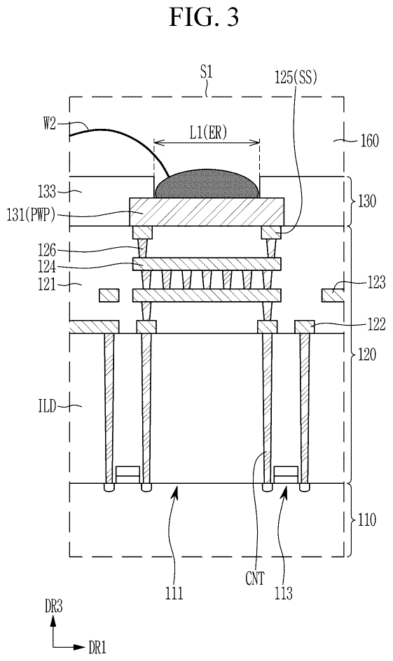

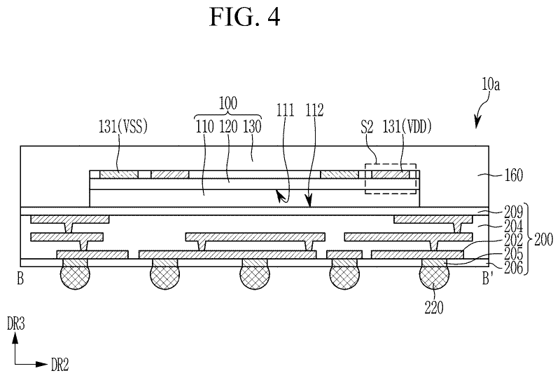

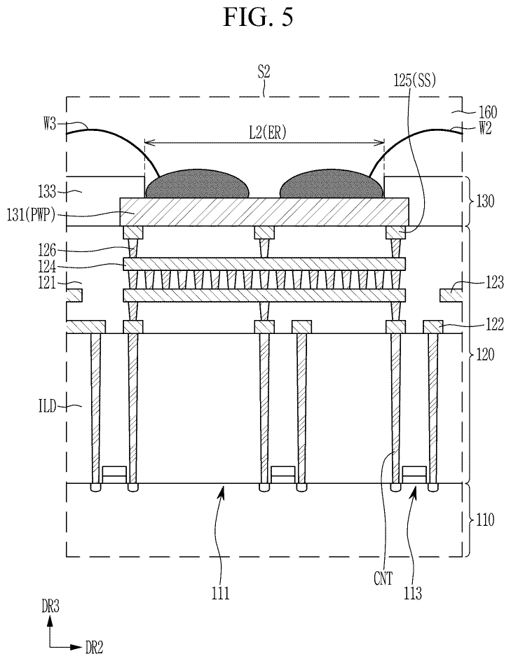

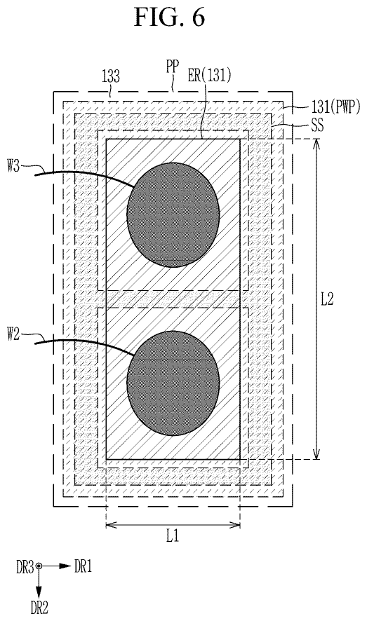

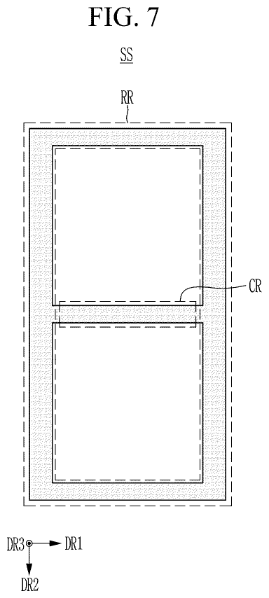

FIG. 1 is a plan view illustrating a semiconductor package according to some example embodiments. FIG. 2 is a cross-sectional view illustrating a section taken along line A-A′ of FIG. 1. FIG. 3 is an enlarged view of the S1 region of FIG. 2. FIG. 4 is a cross-sectional view illustrating a section taken along line B-B′ of FIG. 1. FIG. 5 is an enlarged view of S2 region of FIG. 4. FIG. 6 is an enlarged view of the PP region of FIG. 1. FIG. 7 illustrates a support structure according to some example embodiments.

Referring to FIGS. 1 to 7, a semiconductor package 10a may include a semiconductor chip 100, a package substrate 200 on which the semiconductor chip 100 may be mounted, external connection terminals 220 provided on a lower surface of the package substrate 200, and a sealing component 160.

In the drawing, the semiconductor package 10a is illustrated as including one semiconductor chip 100, but is not limited thereto, and according to some example embodiments, the semiconductor package 10a may be a multi-chip package (MCP) including memory chips of the same type or including semiconductor chips of different types. In addition, although one semiconductor chip 100 is illustrated as being mounted on a package substrate 200 in the drawing, a plurality of semiconductor chips may be mounted on the package substrate 200 according to some example embodiments. According to some example embodiments, a plurality of semiconductor chips may be mounted on a package substrate 200 in the form of a stacked structure stacked in a third direction DR3.

The semiconductor chip 100 may be a memory chip including a memory cell. According to some example embodiments, the semiconductor chip 100 may be, but is not limited to, a volatile memory device or a non-volatile memory device. In case that the semiconductor chip 100 is a volatile memory device, the semiconductor chip 100 may be implemented as SRAM (Static Random Access Memory), DRAM (Dynamic Random Access Memory), etc. According to some example embodiments, in a case that the semiconductor chip 100 is a nonvolatile memory device, the semiconductor chip 100 may be implemented as a flash memory device, a phase-change RAM (PRAM), a magnetic RAM (MRAM), a resistive RAM (RRAM), a ferroelectric RAM (FRAM), a thyristor RAM (TRAM), a read only memory (ROM), a programmable ROM (PROM), an electrically programmable ROM (EPROM), an electrically erasable and programmable ROM (EEPROM), etc.

According to some example embodiments, the semiconductor chip 100 may be a logic chip including a logic circuit. The semiconductor chip (100) may be a host such as a SoC (System on a Chip), or a processor chip such as an AP (Application Processor), a CPU (Central Processing Unit), or an ASIC (Application Specific Integrated Circuit).

The package substrate 200 may mount a semiconductor chip 100 placed on top. The package substrate 200 may redistribute the substrate wire pads 207, 208 arranged on the upper portion by extending them to an external region. Accordingly, the package substrate 200 may be referred to as a redistribution substrate. Additionally, according to some example embodiments, the package substrate 200 may be referred to as a board or a board substrate.

According to some example embodiments, the package substrate 200 may be a ceramic substrate, a rigid printed circuit board, a flexible printed circuit board, a rigid-flexible printed circuit board, an organic substrate, an interposer substrate, etc. Additionally, according to some example embodiments, the package substrate 200 may be manufactured based on an active wafer such as a silicon wafer.

According to some example embodiments, the package substrate 200 may include a wiring structure 202, a substrate insulating layer 204 including the wiring structure 202, and substrate wire pads 207, 208 disposed on top of the wiring structure 202 and the substrate insulating layer 204.

The wiring structure 202 may include wiring lines and vias. Wiring lines may be arranged in a multi-layer structure based on the third direction DR3, and wiring lines between adjacent layers in the third direction DR3 may be connected to each other through vias. The external connection terminal 220 may be placed on the lower surface of the substrate insulating layer 204. The external connection terminal 220 may be placed on the external connection pad 205 and connected to the wiring structure 202 through the external connection pad 205. Additionally, the external connection terminal 220 may be electrically connected to the semiconductor chip 100 through the external connection pad 205, the wiring structure 202, and the substrate wire pad 207, 208.

The first substrate wire pad 207 may be electrically connected to the semiconductor chip 100 in parallel through the second wire W2 and the third wire W3 separated from each other. The first substrate wire pad 207 may be connected to the first chip wire pad 131 through the second and third wire W2, W3. A power voltage may be supplied to the semiconductor chip 100 through the first substrate wire pad 207 and the second and third wire W2, W3. A first power voltage VDD may be provided to the semiconductor chip 100 through at least a portion of the first substrate wire pad 207. The first power voltage VDD may be an operating voltage of the semiconductor chip 100. A second power voltage VSS may be provided to the semiconductor chip 100 through at least a portion of the first substrate wire pad 207. The second power voltage VSS may be the ground voltage of the semiconductor chip 100.

The short side of the first substrate wire pad 207 may be 30 um to 70 um, and preferably 40 um to 60 um. The long side of the first substrate wire pad 207 may be 3 to 4 times based on the diameter of the wires W1 to W3 and may be 80 um to 120 um, preferably 90 um to 110 um. The long side of the first substrate wire pad 207 is longer than the short side of the first substrate wire pad 207, and the ratio of the short side to the long side of the first substrate wire pad 207 may be 1 to x. The above x may be a real number greater than or equal to 1.6. In the drawing, the first substrate wire pad 207 may have a rectangular shape in a plan view, but is not limited thereto and may be modified into various shapes such as an ellipse or an octagon according to some example embodiments.

The second substrate wire pad 208 may be electrically connected to the semiconductor chip 100 through the first wire W1. The second substrate wire pad 208 may be connected to the second chip wire pad 132 through the first wire W1. A signal may be provided to the semiconductor chip 100 through the second substrate wire pad 208 and the first wire W1. For example, data signals and control signals, etc. may be provided to the semiconductor chip 100 through the second substrate wire pad 208.

The substrate wire pads 207, 208 may include copper (Cu), aluminum (Al), molybdenum (Mo), titanium (Ti), gold (Au), silver (Ag), chromium (Cr), tin (Sn), nickel (Ni), antimony (Sb), bismuth (Bi), zinc (Zn), indium (In), palladium (Pd), platinum (Pt), and/or alloys thereof.

Although not illustrated, according to some example embodiments, the semiconductor chip 100 may further include micro bumps or bonding pads bonded in bumpless bonding, etc., arranged on the upper surface of the substrate insulating layer 204 in addition to the substrate wire pads 207, 208.

As illustrated in FIG. 2, the external connection terminal 220 may be placed on the central region of the lower surface of the substrate insulating layer 204 that overlaps the semiconductor chip 100 in a plan view, and on the outer region of the lower surface of the substrate insulating layer 204 based on the central region. The package substrate 200 may relocate an external connection terminal 220 to a wider area than the lower surface of the semiconductor chip 100 through a wiring structure 202. In this way, a package structure in which the external connection terminal 220 is widely arranged beyond the bottom surface of the semiconductor chip 100 is called a fan-out (FO) package structure. According to some example embodiments, the external connection terminal 220 may be a solder ball, but is not limited thereto.

According to some example embodiments, the package substrate 200 may be formed at a wafer level and may be included as a component of a semiconductor package 10a through singulation through sawing or the like. In case that the package substrate (200) is based on a wafer in this way, the semiconductor package 10a may be referred to as a FO-WLP (FO-Wafer Level Package). According to some example embodiments, the package substrate 200 is formed at a panel level and may be included as a component of a semiconductor package 10a through singulation through sawing or the like. Accordingly, the semiconductor package 10a may be referred to as a FO-PLP (FO-Panel Level Package).

A semiconductor chip 100 may include a substrate 110, a wiring layer 120, and a pad layer 130.

The substrate 110 may have a first side 111 and a second side 112 that are opposite to each other. The first side 111 may be an active side, and the second side 112 may be an inactive side and face the package substrate 200. As the active surface of the substrate 110, individual elements 113 (see FIG. 5) may be placed on the first surface 111 of the substrate 110, and the individual elements 113 may include memory elements or circuit elements. The first side 111 may be referred to as the front side surface where individual elements 113 are arranged, and the second side 112 may be referred to as the backside surface.

The substrate 110 may include bulk silicon, silicon-on-insulator (SOI), silicon germanium, silicon germanium on insulator (SGOI), indium antimonide, lead tellurium compound, indium arsenide, indium phosphide, gallium arsenide, and/or gallium antimonide.

The wiring layer 120 may be arranged on the first surface 111 and may include a plurality of wiring lines 122 to 125, a plurality of vias 126, a wiring insulation layer 121 including a plurality of insulating films including a plurality of wiring lines 122 to 125 and a plurality of vias 126, a plurality of contacts CNT, and an interlayer insulation layer ILD (see FIG. 3).

A plurality of wiring lines 122 to 125 and a plurality of vias 126 may be arranged alternately in the third direction DR3. Some of the plurality of wiring lines 122 to 125 and some of the plurality of vias 126 may be arranged in a multi-layer structure within the wiring layer 120 as a single wiring structure.

The upper wiring line 125 placed at the top among the plurality of wiring lines 122 to 125 based on the substrate 110, may include a support structure SS that contacts the lower surface of the first chip wire pad 131. A description of the support structure SS is provided below together with a description of the first chip wire pad 131.

The plurality of wiring lines 122-125 and the plurality of vias 126 may include a conductive metal material, for example, aluminum (Al), copper (Cu), tin (Sn), nickel (Ni), gold (Au), platinum (Pt), and/or alloys thereof.

The wiring insulation layer 121 may include a plurality of insulating films that are stacked in the third direction DR3 and include a plurality of wiring lines 122 to 125 and a plurality of vias 126. According to some example embodiments, the plurality of insulating films may be disposed as a single material layer. The plurality of insulating films may include silicon oxide, carbon-doped silicon oxide, silicon carbon nitride, and the like.

The plurality of contacts CNT may be extended in the third direction DR3 and may connect a plurality of wiring lines 122 to 125 to individual elements 113 within the wiring layer 120. A plurality of contacts CNT may be connected to a lower wiring line 122 (e.g., a lowermost wiring line) placed at the lowest among a plurality of wiring lines 122 to 125 based on the substrate 110.

The plurality of contact CNT may include tungsten (W), copper (Cu), tantalum (Ta), titanium (Ti), cobalt (Co), manganese (Mn), tantalum nitride (TaN), titanium nitride (TiN), aluminum nitride (AlN), tungsten nitride (WN) and/or combinations thereof.

The interlayer insulation layer ILD may cover the first surface 111 and include the plurality of contacts CNT. The interlayer insulation layer ILD may mutually insulate individual elements 113 and wiring lines within the wiring layer 120. The interlayer insulation layer ILD may include silicon oxide, carbon-doped silicon oxide, silicon carbon nitride, or the like. Unlike that illustrated in FIG. 3, according to some example embodiments, the interlayer insulation layer ILD and the wiring insulation layer 121 may be arranged as a single material layer.

The pad layer 130 may be placed on the wiring layer 120. The pad layer 130 may include a plurality of chip wire pads 131, 132 and a passivation film 133. A semiconductor chip 100 may be electrically connected to a package substrate 200 through a plurality of chip wire pads 131, 132 and wires W1 to W3. The plurality of chip wire pads 131, 132 may be non-overlapping with each other in a plan view.

The wires W1 to W3 may contain gold (Au), copper (Cu), aluminum (Al), and/or alloys thereof. The wiring diameter for the wires W1 to W3 may be 15 um to 40 um, and preferably 15 um to 35 um.

The first chip wire pad 131 may be electrically connected to the package substrate 200 in parallel through the second wire W2 and the third wire W3 separated from each other. The semiconductor chip 100 may receive a power voltage through the first chip wire pad 131 and the second and third wires W2, W3, and the first chip wire pad 131 may be a power wire pad PWP. Through at least a portion of the first chip wire pad 131, the semiconductor chip 100 may receive the first power voltage VDD. Through at least a portion of the first chip wire pad 131, the semiconductor chip 100 may receive a second power voltage VSS. Through the first chip wire pad 131, which is a power wire pad PWP, and a plurality of wires W2, W3, the semiconductor chip 100 improves impedance performance for power voltage and improve the integrity of received power.

The first chip wire pad 131 may include an exposure region ER exposed by the passivation film 133. The second wire W2 and the third wire W3, which are separated from each other, may be bonded on the exposure region ER, and the second wire W2 and the third wire W3 may be arranged in the second direction DR2.

The exposure region ER may have a short side of a first length L1 extending in the first direction DR1. The first length L1 may be 30 um to 70 um, preferably 40 um to 60 um. The exposure region ER may have a long side of a second length L2 extending in the second direction DR2. The second length L2 may be 3 to 4 times the diameter of the wires W1 to W3 and may be 80 um to 120 um, preferably 90 um to 110 um. The second length L2 is longer than the first length L1, and the ratio of the first length L1 to the second length L2 may be 1 to x. The x may be a real number greater than or equal to 1.6. According to some example embodiments, in case that two wires W2, W3 are bonded on an exposure region ER, the ratio of the first length L1 to the second length L2 may be 1 to x, where x may be a real number between 1.6 and 2.2. In FIG. 6, the exposure area (ER) has a rectangular shape in a plan view, but is not limited thereto and may be modified into various shapes such as an ellipse or an octagon according to some example embodiments.

The first chip wire pad 131 may be overlapped with the support structure SS in a plan view, and the support structure SS may be in contact with the lower surface of the first chip wire pad 131. The support structure SS may include a ring region RR and a center region CR. The support structure SS may have an ‘8’ tube shape, which is a closed structure, at the bottom of the first chip wire pad 131. The ring region RR and the center region CR may be included in the upper wiring line 125 (e.g., an uppermost wiring line) and may be arranged at the same height based on the substrate 110.

The ring region RR may be arranged along the boundary of the first chip wire pad 131 in a plan view. According to some example embodiments, the ring region RR may be arranged so as not to overlap with the exposure region ER in a plan view. The center region CR may extend in one direction within the ring region RR, and according to some example embodiments, the center region CR may extend in the first direction DR1. The center region CR may be disposed between the regions where the second and third wires W2, W3 are bonded in a plan view, and may be disposed so as not to overlap with the second and third wires W2, W3 in a plan view.

The support structure SS may surround the plurality of wires W2, W3, arranged so as not to overlap with the plurality of wires W2, W3 in a plan view. When performing a bonding operation on the plurality of wires W2, W3 on a first chip wire pad 131, the support structure SS can firmly support the first chip wire pad 131 while protecting the individual elements 113 through the above structure. The support structure SS can prevent or reduce in likelihood cracks from being generated in individual elements 113 placed under the wire pad having a multiple bonding structure, and can prevent or reduce in likelihood the wiring insulation layer 121 placed under the chip wire pad from collapsing.

The second chip wire pad 132 may be electrically connected to the package substrate 200 through the first wire W1. Through the second chip wire pad 132 and the first wire W1, the semiconductor chip 100 may transmit and receive signals to the outside. For example, through the second chip wire pad 132, the semiconductor chip 100 may receive data signals, control signals, etc. At least a portion of the second chip wire pad 132 may be exposed by the passivation film 133, and the first wire W1 may be bonded on the exposed area.

The plurality of chip wire pads 131, 132 may include copper (Cu), aluminum (Al), molybdenum (Mo), titanium (Ti), gold (Au), silver (Ag), chromium (Cr), tin (Sn), nickel (Ni), antimony (Sb), bismuth (Bi), zinc (Zn), indium (In), palladium (Pd), platinum (Pt), and/or alloys thereof.

Although not illustrated, the passivation film 133 may include a plurality of stacked insulating films. For example, the passivation film 133 may be sequentially stacked and include an organic passivation film including an oxide film and an inorganic passivation film including a nitride film. The passivation film 133 may include silicon oxide, silicon nitride, silicon carbon nitride, and/or the like.

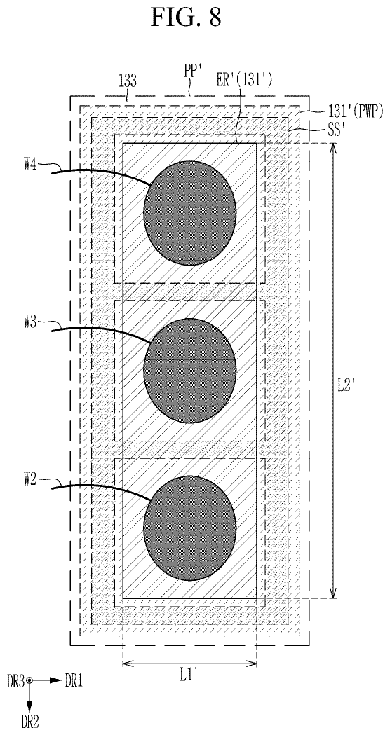

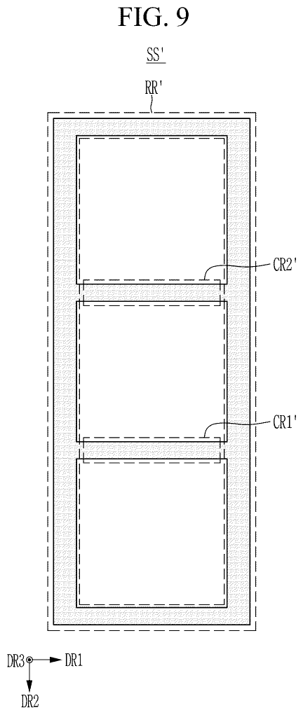

FIGS. 8 and 9 illustrate a chip wire pad and a support structure according to some example embodiments. Each of the first chip wire pads 131′ and the support structure SS′ of FIGS. 8 and 9 may correspond to the first chip wire pads 131 and the support structure SS of FIGS. 1 to 7, respectively. For ease of explanation hereinafter, the first chip wire pad 131′ and the support structure SS′ will be described with focus on the differences from the first chip wire pads 131 and the support structure SS.

Referring to FIGS. 8 and 9, the first chip wire pad 131′ can be electrically connected to the package substrate 200 in parallel through second to fourth wires W2 to W4 separated from each other. The semiconductor chip 100 may receive a power voltage through the first chip wire pad 131′ and the second to fourth wires W2 to W4, and the first chip wire pad 131′ may be a power wire pad PWP. Through the first chip wire pad 131′, which is a power wire pad PWP, and the plurality of wires W2, W3, W4, the semiconductor chip 100 improves impedance performance for power voltage and/or improves the integrity of received power.

The first chip wire pad 131′ may include an exposure area ER′ exposed by a passivation film 133. The second to fourth wires W2 to W4 separated from each other may be bonded on the exposure area ER′, and the second to fourth wires W2 to W4 may be arranged in the second direction DR2.

The exposure region ER′ may have a short side of a first length L1′ extending in the first direction DR1. The first length L1′ may be 30 um to 70 um, preferably 40 um to 60 um. The exposure region ER′ may have a long side of a second length L2′ extending in the second direction DR2. The second length L2′ may be 4.5 to 6 times the diameter of the wires W1 to W4 and may be 120 um to 180 um, preferably 130 um to 170 um. The second length L2′ may be longer than the first length L1′, and a ratio of the first length L1′ to the second length L2′ may be 1 to y. The y may be a real number greater than or equal to 2.3. According to some example embodiments, in case that three wires W2, W3, W4 are bonded on the exposure region ER′, the ratio of the first length L1′ to the second length L2′ may be 1 to y, and the y may be a real number between 2.3 and 3. In FIG. 8, the exposure region ER′ has a rectangular shape in a plan view, but is not limited thereto and may be modified into various shapes such as an ellipse or an octagon according to some example embodiments.

The first chip wire pad 131′ may be overlapped with the support structure SS′ in a plan view, and the support structure SS′ may be in contact with the lower surface of the first chip wire pad 131′. The support structure SS′ may include a ring region RR′ and first and second center regions CR1′, CR2′. The support structure SS′ may have a form in which three tubes in a closed structure are connected at the bottom of the first chip wire pad 131′.

The first and second center regions CR1′, CR2′ may extend in one direction within the ring region RR′, and according to some example embodiments, the first and second center region CR1′, CR2′ may extend in the first direction DR1. The first center region CR1′ may be disposed between the regions where the second and third wires W2, W3 are bonded in a plan view, and may be disposed so as not to overlap with the second and third wires W2, W3 in a plan view. The second center region CR2′ may be disposed between the regions where the third and fourth wires W3, W4 are bonded in a plan view, and may be disposed so as not to overlap with the third and fourth wires W3, W4 in a plan view.

The support structure SS′ may surround the plurality of wires W2, W3, W4 while being disposed so as not to overlap with the plurality of wires W2, W3, W4 in a plan view. When performing a bonding operation on the plurality of wires W2, W3, W4 on the first chip wire pad 131′, the support structure SS′ can firmly support the first chip wire pad 131′ while protecting individual elements placed thereunder through the above structure. The support structure SS′ can prevent or reduce in likelihood cracks from being generated in individual elements placed under the wire pad having a multiple bonding structure and can prevent or reduce in likelihood the insulation layer placed under the chip wire pad from collapsing. Although FIGS. 1 to 9 illustrate that two or three wires are bonded on the chip wire pad, but this is not limited thereto, and the number of wires bonded on the chip wire pad may vary depending on the example embodiment.

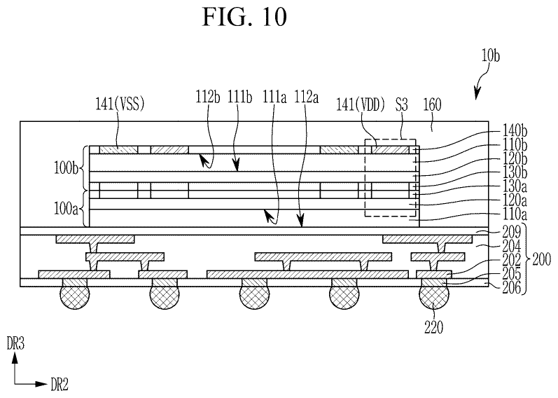

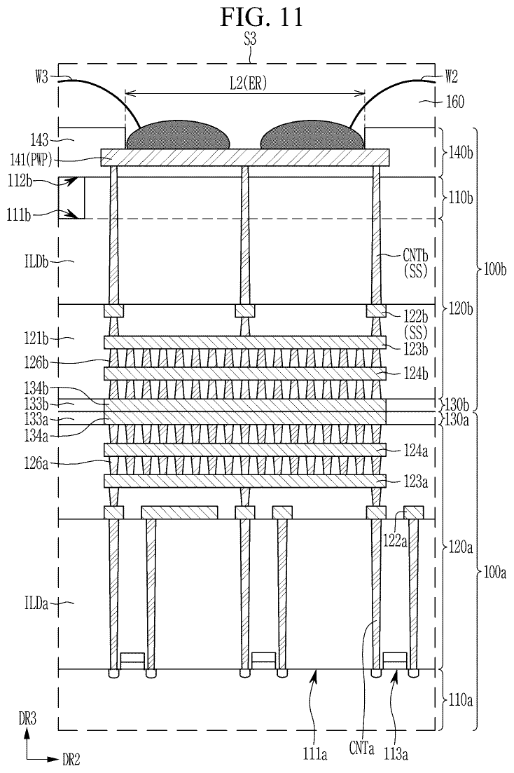

FIG. 10 is a cross-sectional view illustrating a semiconductor package according to some example embodiments. FIG. 11 is an enlarged view of S3 region of FIG. 10. Each of the package substrates 200 and the a-th and b-th semiconductor chips 100a, 100b in the semiconductor packages 10b of FIGS. 10 and 11 may correspond to each of the package substrates 200 and the semiconductor chip 100 in the semiconductor packages 10a of FIGS. 1 to 7, respectively. For ease of explanation hereinafter, the semiconductor package 10b of FIGS. 10 and 11 will be described with a focus on differences from the semiconductor package 10a of FIGS. 1 to 7.

Referring to FIGS. 10 and 11, a semiconductor package 10b may include an a-th semiconductor chip 100a and a b-th semiconductor chip 100b that are stacked in a third direction DR3. Additionally, the stacked structure for the a-th and b-th semiconductor chips 100a, 100b can be mounted on a package substrate 200.

The a-th and b-th semiconductor chips 100a, 100b may be operated as one memory device. The a-th semiconductor chip 100a may be a logic chip, and the b-th semiconductor chip 100b may be a memory chip. The a-th semiconductor chip 100a may be a logic chip including a logic circuit, and the logic chip may be a control logic that controls memory elements of the b-th semiconductor chip 100b.

According to some example embodiments, the a-th semiconductor chip 100a and the b-th semiconductor chip 100b may be operated as one processor. According to some example embodiments, each of the a-th semiconductor chip 100a and the b-th semiconductor chip 100b may be a chiplet that performs some functions of a processor chip such as an ASIC or an AP as a part of a host such as an SOC, but is not limited thereto.

The a-th and b-th semiconductor chips 100a, 100b may be connected to the second and third wires W2, W3 through the first chip wire pad 141 placed on the upper surface of the b-th semiconductor chip 100b, and may receive a power voltage from the package substrate 200. The first chip wire pad 141 may correspond to the first chip wire pad 131 of FIGS. 1 to 7 and may be a power wire pad PWP.

The a-th semiconductor chip 100a may include an a-th substrate 110a, an a-th wiring layer 120a, and an a-th pad layer 130a, and the b-th semiconductor chip 100b may include a b-th substrate 110b, a b-th wiring layer 120b, a b-th pad layer 130b, and a backside pad layer 140b.

The a-th substrate 110a may have a first surface 111a and a second surface 112a that are opposed to each other. The a-th substrate 110a may correspond to the substrate 110 of FIGS. 1 to 7. The first surface 111a may be an active surface and may face the b-th semiconductor chip 100b. The second side 112a may be an inactive side and may face the package substrate 200. As the active surface of the a-th substrate 110, an a-th individual element 113a may be disposed on the first surface 111a of the a-th substrate 110a, and the a-th individual element 113a may include circuit elements. The first side 111a may be the front side where the a-th individual element 113a is disposed, and the second side 112a may be the back side.

The a-th wiring layer 120a may be placed on the first surface 111a and may include a plurality of a-th wiring lines 122a to 124a, a plurality of a-th vias 126a, a plurality of a-th wiring insulating layers 121a including a plurality of insulating films including a plurality of a-th wiring lines 122a to 124a and a plurality of a-th vias 126a, a plurality of a-th contacts CNTa, and an a-th interlayer insulation layer ILDa.

Each of the plurality of a-th wiring lines 122a to 124a, the plurality of a-th vias 126a, the a-th wiring insulation layers 121a, the plurality of a-th contacts CNTa, and the a-th interlayer insulation layer ILDa may correspond to the plurality of wiring lines 122 to 125, the plurality of vias 126, the wiring insulation layer 121, the plurality of contacts CNT, and the interlayer insulation layer ILD of FIGS. 1 to 7, respectively.

Among the plurality of a-th wiring lines 122a to 124a, the a-th upper wiring line 124a may be connected to the plurality of a-th bonding pads 134a of the a-th pad layer 130a through the plurality of a-th vias 126a.

The a-th pad layer 130a may be placed on the a-th wiring layer 120a. The a-th pad layer 130a may include a plurality of a-th bonding pads 134a and a a-th passivation film 133a.

The b-th pad layer 130b can be placed on the a-th pad layer 130a. The b-th pad layer 130b may include a plurality of b-th bonding pads 134b and a b-th passivation film 133b.

The plurality of a-th bonding pads 134a exposed by the a-th passivation film 133a and the plurality of b-th bonding pads 134b exposed by the b-th passivation film 133b may be directly bonded in a pad-to-pad form by a hybrid bonding method. The bonding method may be a Cu—Cu bonding method, and according to some example embodiments, the a-th and b-th bonding pads 134a, 134b may be aluminum or tungsten. The plurality of a-th bonding pads 134a and the plurality of b-th bonding pads 134b may be in contact (e.g., direct contact) with each other without bump arrangement, thereby forming a bonding structure together with the a-th passivation film 133a and the b-th passivation film 133b.

The b-th wiring layer 120b may be placed on the b-th pad layer 130b and may include a plurality of b-th wiring lines 122b to 124b, a plurality of b vias 126b, a b-th wiring insulating layer 121b including a plurality of insulating films including the plurality of b-th wiring lines 122b to 124b and the plurality of b-th vias 126b, a plurality of b-th contacts CNTa, and a b-th interlayer insulation layer ILDb.

Each of the plurality of b-th wiring lines 122b to 124b, the plurality of b-th vias 126b, the b-th wiring insulation layers 121b, the plurality of b-th contacts CNTb, and the b-th interlayer insulation layer ILDb may correspond to the plurality of wiring lines 122 to 125, the plurality of vias 126, the wiring insulation layer 121, the plurality of contacts CNT, and the interlayer insulation layer ILD of FIGS. 1 to 7, respectively.

Among the plurality of b-th wiring lines 122b to 124b, the b-th upper wiring line 124b may be connected to the plurality of b-th bonding pads 134b of the b-th pad layer 130b through the plurality of b-th vias 126b. Among the plurality of b-th wiring lines 122b to 124b, the b-th lower wiring line 122b may include a support structure SS that overlaps the first chip wire pad 141 in a plan view. The support structure SS may have a form in which a tube in closed structure is connected in a plan view, at the bottom of the first chip wire pad 141, as described in FIGS. 1 to 9. The upper wiring line 124b of the b-th substrate 110b may be a wiring line placed at top among the plurality of b-th wiring lines 122b to 124b, and the lower wiring line 122b may be a wiring line placed at the lowest among the plurality of b-th wiring lines 122b to 124b based on the b-th substrate 110b.

A plurality of b-th contacts CNTb extend in the third direction DR3 and may connect between a plurality of b-th wiring lines 122b to 124b in the b-th wiring layer 120b and the first chip wire pad 141. At least some of the plurality of b-th contacts CNTb may be interposed between the b-th lower wiring line 122b and the first chip wire pad 141, and the plurality of b-th contacts CNTb interposed between the b-th lower wiring line 122b and the first chip wire pad 141 may support the first chip wire pad 141 as part of the support structure SS. At least a portion of the b-th lower wiring line 122b that overlaps the first chip wire pad 141 in a plan view and at least a portion of the plurality of b-th contacts CNTb can support the first chip wire pad 141 as a support structure SS. According to some example embodiments, the b-th substrate 110b may not be disposed in an area where the plurality of b-th contacts CNTb, which are support structures SS connected to the first chip wire pad 141, are placed.

The b-th substrate 110b may have a third side 111b and a fourth side 112b that are opposite to each other. The b-th substrate 110b may correspond to the substrate 110 of FIGS. 1 to 7. The third side 111b may be an active side and may face the a-th semiconductor chip 100a, and the fourth side 112b may be an inactive side. Although not illustrated, according to some example embodiments, the third side 111b may be the front side where individual elements are placed, and the fourth side 112b may be the back side.

The backside layer 140b may be disposed on the fourth surface 112b of the b-th substrate 110b. The backside layer 140b may include a first chip wire pad 141 and a backside passivation film 143. Each of the first chip wire pads 141 and the backside passivation film 143 may correspond to the first chip wire pads 131 and the passivation film 133 of FIGS. 1 to 7, respectively.

The a-th and b-th semiconductor chips 100a, 100b may be electrically connected to the package substrate 200 through the first chip wire pad 141 and the second and third wires W2, W3 and may receive power voltage VDD, VSS. The a-th and b-th semiconductor chips 100a, 100b improve impedance performance for a power voltage and/or improve the integrity of received power through the first chip wire pad 141 and the second and third wires W2, W3.

The support structure SS can surround a plurality of wires W2, W3 while being disposed so as not to overlap with the plurality of wires W2, W3 in a plan view. When performing a bonding operation on a plurality of wires W2, W3 on the first chip wire pad 141, the support structure SS can firmly support the first chip wire pad 141 while protecting the a-th individual element 113a through the structure as described above. The support structure SS can prevent or reduce in likelihood cracks from being generated in the a-th individual element 113a disposed under the wire pad having a multiple bonding structure, and/or can prevent or reduce in likelihood the b-th interlayer insulating layer ILDb disposed under the chip wire pad from collapsing.

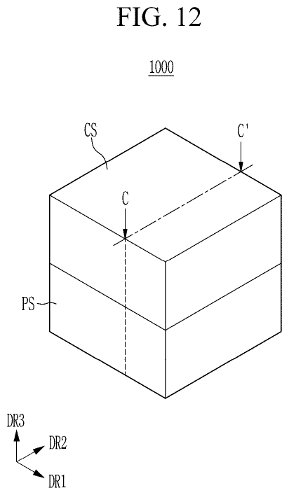

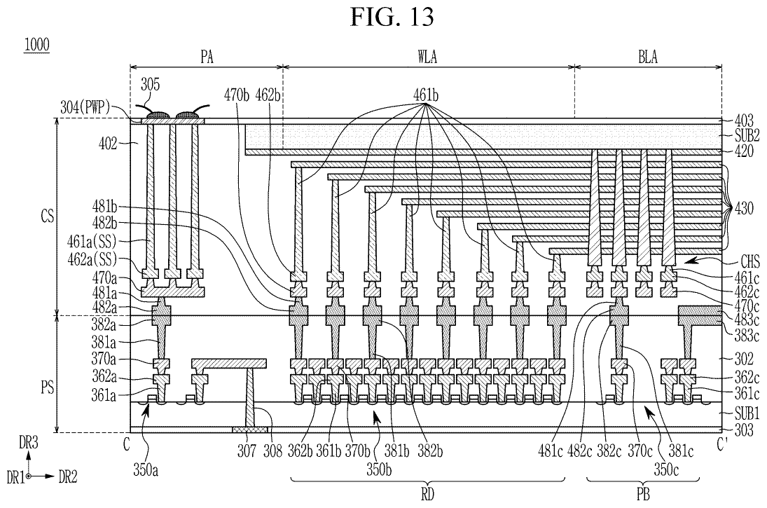

FIGS. 12 and 13 illustrate a memory device to which a structure of a semiconductor chip according to some example embodiments is applied. Specifically, FIG. 13 is a cross-sectional view illustrating a section taken along line C-C′ of FIG. 12.

Referring to FIGS. 12 and 13, the memory device 1000 may have a C2C (chip to chip) structure. The C2C structure may mean fabricating an upper chip including a cell array structure CS on a first wafer, fabricating a lower chip including a peripheral circuit structure PS on a second wafer different from the first wafer, and then connecting the upper chip and the lower chip to each other by a bonding method. For example, the above bonding method may mean a method of electrically connecting a bonding metal disposed in the top metal layer of the upper chip and a bonding metal disposed in the top metal layer of the lower chip. For example, in case that the bonding metal is copper (Cu), the bonding method may be a Cu—Cu bonding method, and according to some example embodiments, the bonding metal may be aluminum or tungsten.

The memory device 1000 may be a nonvolatile memory device, and the memory device 1000 may include a cell array structure CS and a peripheral circuit structure PS. The cell array structure CS and the peripheral circuit structure PS are stacked in a third direction DR3, so that the cell array structure CS and the peripheral circuit structure PS can overlap each other at least partially in the third direction DR3. Each of the cell array structure CS and the peripheral circuit structure PS may correspond to the b-th semiconductor chip 100b and the a-th semiconductor chip 100a of FIG. 10 and FIG. 11, respectively.

Each of the cell array structure CS and the peripheral circuit structure PS of the memory device 1000 may include an external pad bonding area PA, a word line bonding area WLA, and a bit line bonding area BLA.

The peripheral circuit structure PS may include a first substrate SUB1, an interlayer insulation layer 302, a plurality of circuit elements 350a, 350b, 350c disposed on the first substrate SUB1, a first metal layer 362a, 362b, 362c connected to each of the plurality of circuit elements 350a, 350b, 350c through a plurality of contacts 361a, 361b, 361c, and a second metal layer 370a, 370b, 370c disposed on the first metal layer 362a, 362b, 362c. According to some example embodiments, the first metal layer 362a, 362b, 362c and the plurality of contacts 361a, 361b, 361c may include relatively high resistivity tungsten, and the second metal layer 370a, 370b, 370c may include relatively low resistivity copper.

In the drawing, only the first metal layer 362a, 362b, 362c and the second metal layer 370a, 370b, 370c are illustrated, but this is not limited to them, and at least one more metal layer may be further disposed on the second metal layer 370a, 370b, 370c. At least some of the one or more metal layers disposed on upper of the second metal layer 370a, 370b, 370c may include aluminum or the like having lower resistance than copper included in the second metal layer 370a, 370b, 370c.

An interlayer insulation layer 302 is disposed on the first substrate SUB1 to cover a plurality of circuit elements 350a, 350b, 350c, a first metal layer 362a, 362b, 362c, and a second metal layer 370a, 370b, 370c, and may include an insulating material such as silicon oxide, silicon nitride, or the like.

A cell array structure CS may provide at least one memory block. The cell array structure CS may include a second substrate SUB2 and a common source line 420. On the second substrate SUB2, a plurality of conductive lines 430 may be stacked along a direction perpendicular to the upper surface of the second substrate SUB2 (i.e., the third direction DR3). According to some example embodiments, the plurality of conductive lines 430 may include string selection lines and ground selection lines placed at the upper and lower ends, respectively, and a plurality of word lines may be placed between the string selection lines and the ground selection lines.

In the bit line bonding area BLA, the channel structure CHS may extend in a third direction DR3 perpendicular to the upper surface of the second substrate SUB2 and may penetrate the plurality of conductive lines 430. The channel structure CHS may include a data storage layer, a channel layer, and a buried insulation layer. According to some example embodiments, memory cells may be arranged at points where the plurality of word lines intersect along the channel structure CHS. The channel layer may be electrically connected to a plurality of contacts 461c, a first metal layer 462c, and a second metal layer 470c. For example, the plurality of contacts 461c may be bit line contacts, and the second metal layer 470c may be a plurality of bit lines. According to some example embodiments, the bit line of the second metal layer 470c may extend along a first direction DR1 parallel to the upper surface of the second substrate SUB2.

An upper bonding metal 481c, 482c may be disposed on the second metal layer 470c of the bit line bonding area BLA. In the bit line bonding area BLA, the upper bonding metal 481c, 482c of the cell array structure CS may be in contact with and electrically connected to the lower bonding metal 381c, 382c of the peripheral circuit structure PS by a bonding method.

The area where the channel structure CHS and bit lines are disposed may be defined as the bit line bonding area BLA. The bit line of the second metal layer 470c may be electrically connected to the circuit element 350c included in a page buffer PB of the peripheral circuit structure PS in the bit line bonding area BLA. For example, the bit line may be connected to the upper bonding metal 481c, 482c of the cell array structure CS. Accordingly, the page buffer PB may be connected to the bit line through bonding metals 381c, 382c, 481c, 482c. According to some example embodiments, at least some of the circuit elements 350c of the page buffer PB may be disposed to overlap with the bonding metals 381c, 382c, 481c, 482c in the third direction DR3. According to some example embodiments, the page buffer PB may latch data that is or will be stored in a memory cell of a channel structure CHS.

In the word line bonding area WLA, the plurality of conductive lines 430 may extend along a first direction DR1 parallel to the upper surface of the second substrate SUB2 and can be connected to a plurality of cell contacts 461b. A plurality of cell contacts 461b may be connected to a plurality of conductive lines 430 in pad areas where at least some of the plurality of conductive lines 430 extend to different lengths along the second direction DR2 to provide landing points for the plurality of cell contacts 461b. A first metal layer 462b and a second metal layer 470b may be sequentially connected to the upper portion of a plurality of cell contacts 461b connected to the plurality of conductive lines 430.

An upper bonding metal 481b, 482b may be disposed on the second metal layer 470b of the word line bonding area WLA. In the word line bonding area WLA, the upper bonding metal 481b, 482b of the cell array structure CS may be in contact with and electrically connected to the lower bonding metal 381b, 382b of the peripheral circuit structure PS by a bonding method.

The plurality of cell contacts 461b may be connected to the peripheral circuit structure PS through the upper bonding metal 481b, 482b of the cell array structure CS and the lower bonding metal 381b, 382b of the peripheral circuit structure PS in the word line bonding area WLA.

The plurality of cell contacts 461b may be electrically connected to circuit elements 350b included in a row decoder RD in the peripheral circuit structure PS. According to some example embodiments, the operating voltage of the circuit element 350b providing the row decoder RD may be different from the operating voltage of the circuit element 350c providing the page buffer PB. For example, the operating voltage of circuit elements 350c providing a page buffer PB may be higher than the operating voltage of circuit elements 350b providing a row decoder RD.

Input/output pads 304, 307 may be disposed in the external pad bonding area PA. A lower insulating film 303 covering the lower surface of the first substrate SUB1 may be disposed on the lower portion of the first substrate SUB1, and a first input/output pad 307 may be disposed on the lower insulating film 303. The first input/output pad 307 may be connected to at least one of a plurality of circuit elements 350a, 350b, 350c disposed in the peripheral circuit structure PS through the first input/output contact 308.

Although not illustrated in FIG. 13, the first input/output pad 307 may be separated from the first substrate SUB1 by the lower insulating film 303, and a side insulating film is interposed between the first input/output contact 308 and the first substrate SUB1, so that the first input/output contact 308 and the first substrate SUB1 can be electrically separated.

An upper insulating film 403 covering the upper surface of the second substrate SUB2 may be disposed on the upper substrate SUB2, and a second input/output pad 304 may be placed on the upper insulating film 403. The second input/output pad 304 may be connected to at least one of a plurality of circuit elements 350a, 350b, 350c disposed in the peripheral circuit structure PS through the second input/output contact 461a. A first metal layer 462a and a second metal layer 470a may be sequentially stacked on top of the second input/output contact 461a. The first and second input/output contacts 461a, 308 may include a conductive material such as a metal, a metal compound, or polysilicon.

An upper bonding metal 481a, 482a may be disposed on the second metal layer 470a of the external pad bonding area PA. In the external pad bonding area PA, the upper bonding metal 481a, 482a of the cell array structure CS may be in contact with and electrically connected to the lower bonding metal 381a, 382a of the peripheral circuit structure PS by a bonding method.

Accordingly, at least one of the plurality of circuit elements 350a, 350b, 350c may be connected to the second input/output pad 304 via bonding metals 381a, 382a, 481a, 482a. The plurality of circuit elements 350a, 350b, 350c within the memory device 1000 may receive a power voltage through the second input/output pad 304.

At least some of the second input/output pads 304 may be power wire pads PWP, and at least some of the second input/output pads 304 may be exposed by the upper insulating film 403. A plurality of wires 305 separated from each other may be bonded in parallel on the second input/output pad 304. Through the second input/output pad 304, which is a power wire pad PWP, and the plurality of wires 305, the memory device 1000 can improve impedance performance for the power voltage and improve the integrity of the received power.

The first metal layer 462a and the second input/output contact 461a overlapped under the second input/output pad 304 in a plan view may be a support structure SS for the second input/output pad 304.

The support structure SS may correspond to the support structure SS of FIGS. 10 and 11, and the support structure SS may be disposed so as not to overlap with the plurality of wires 305 in a plan view, and may surround the plurality of wires 305, respectively. When performing a bonding operation on a plurality of wires 305 on a second input/output pad 304, the support structure SS can firmly support the second input/output pad 304 while protecting a plurality of circuit elements 350a within the external pad bonding area PA through the above structure. The support structure SS can prevent or reduce in likelihood cracks from being generated in the plurality of circuit elements 350a within the external pad bonding area PA disposed under a second input/output pad 304 and/or can prevent or reduce in likelihood an interlayer insulation layer 402 disposed under the input/output pad from collapsing.

The area that is non-overlapping with the multiple challenge lines 430 in the third direction DR3 may be defined as an external pad bonding area PA. According to some example embodiments, the second substrate SUB2 and the common source line 420 may not be disposed in the area where the second input/output contact 461a is disposed. Additionally, the second input/output pad 304 may be disposed so as not to overlap with a plurality of conductive lines 430 with respect to the third direction DR3. The second input/output pad 304 may be separated from the second substrate SUB2 in a direction parallel to the upper surface of the second substrate SUB2 and connected to a second input/output contact 461a penetrating the interlayer insulation layer 402 of the cell array structure CS in the third direction DR3.

In each of the external pad bonding area PA and bit line bonding area BLA included in the cell array structure CS and the peripheral circuit structure PS, the metal pattern of the uppermost metal layer may exist as a dummy pattern, or the uppermost metal layer may be empty.

Corresponding to the lower metal pattern disposed on the upper metal layer of the peripheral circuit structure PS in the external pad bonding area PA, an upper metal pattern having the same shape as the lower metal pattern of the peripheral circuit structure PS may be disposed on the upper metal layer of the cell array structure CS.

Additionally, in the bit line bonding area BLA, an upper metal pattern 483c having the same shape as the lower metal pattern 383c may be disposed on the uppermost metal layer of the cell array structure CS corresponding to the lower metal pattern 383c disposed on the uppermost metal layer of the peripheral circuit structure PS. A contact may not be disposed on the upper metal pattern 483c disposed on the uppermost metal layer of the cell array structure CS.

The lower bonding metal 381a, 382a, 381b, 382b, 381c, 382c and the upper bonding metal 481a, 482a, 481b, 482b, 481c, 482c may include aluminum, copper, or tungsten.

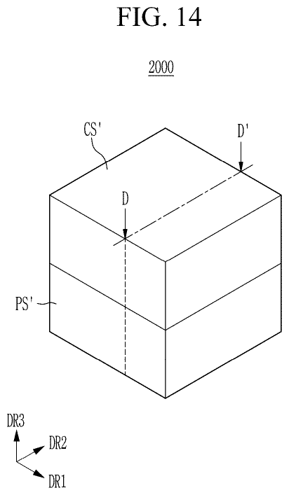

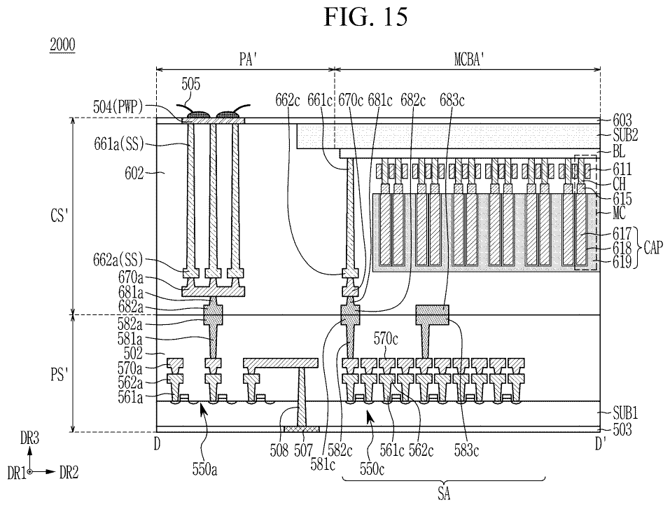

FIGS. 14 and 15 illustrate a memory device to which a structure of a semiconductor chip according to some example embodiments is applied. Specifically, FIG. 15 is a cross-sectional view illustrating a section taken along line D-D′ of FIG. 14.

Referring to FIGS. 14 and 15, the memory device 2000 may have a C2C (chip to chip) structure. The memory device 2000 may be a volatile memory device, and the memory device 2000 may include a cell array structure CS′ and a peripheral circuit structure PS′. The cell array structure CS′ and the peripheral circuit structure PS′ are stacked in a third direction DR3, so that the cell array structure CS′ and the peripheral circuit structure PS′ may overlap each other at least partially in the third direction DR3. Each cell array structure CS′ and peripheral circuit structure PS′ may correspond to the b-th semiconductor chip 100b and the a-th semiconductor chip 100a of FIG. 10 and FIG. 11, respectively.

Each of the cell array structure CS′ and the peripheral circuit structure PS′ of the memory device 2000 may include an external pad bonding area PA′ and a memory cell bonding area MCBA′.

The peripheral circuit structure PS′ may include a first substrate SUB1, an interlayer insulation layer 502, a plurality of circuit elements 550a, 550c disposed on the first substrate SUB1, a first metal layer 562a, 562c connected to each of the plurality of circuit elements 550a, 550c through a plurality of contacts 561a, 561c, and a second metal layer 570a, 570c disposed on the first metal layer 562a, 562c. According to some example embodiments, the first metal layer 562a, 562c and the plurality of contacts 561a, 561c may include relatively high resistivity tungsten, and the second metal layer 570a, 570c may include relatively low resistivity copper.

In the drawing, only the first metal layer 562a, 562c and the second metal layer 570a, 570c are illustrated, but this is not limited to them, and at least one more metal layer may be placed on the second metal layer 570a, 570c. At least some of the one or more metal layers placed on top of the second metal layer 570a, 570c may include aluminum or the like having lower resistance than copper included in the second metal layer 570a, 570c.

The interlayer insulating layer 502 is disposed on the first substrate SUB1 to cover a plurality of circuit elements 550a, 550c, the first metal layer 562a, 562c, and the second metal layer 570a, 570c, and may include an insulating material such as silicon oxide, silicon nitride, or the like.

A cell array structure CS can provide at least one memory cell array. The cell array structure CS may include a second substrate SUB2 and a bit line BL. The bit line BL may be arranged to extend in the second direction DR2 parallel to the lower surface of the second substrate SUB2.

In the memory cell bonding area MCBA′, a plurality of memory cells MC can extend in a direction perpendicular to the upper surface of the second substrate SUB2. In the memory cell bonding area MCBA′, a first metal layer 662c connected to each bit line BL and a second metal layer 670c connected on the first metal layer 662c may be disposed. According to some example embodiments, the first metal layer 662c may include relatively high resistivity tungsten, and the second metal layer 670c may include relatively low resistivity copper. A plurality of memory cells MC may be electrically connected to the first metal layer 662c and the second metal layer 670c through a bit line BL and a plurality of contacts 661c. For example, the plurality of contacts 661c may be a bit line contact.

According to some example embodiments, the memory cell MC may have a 1T1C structure and include a vertical channel transistor VCT. A memory cell MC may include a bit line BL, a memory vertical channel layer CH, a plurality of gate electrodes 611, a capacitor contact 615, and a capacitor structure CAP. The above vertical channel transistor may refer to a structure in which a memory vertical channel layer CH extends along a third direction DR3 that is vertical from a second substrate SUB2.

The memory vertical channel layers CH may be arranged spaced apart from each other in the second direction DR2 on the bit line BL. Although not illustrated, the memory vertical channel layers CH may be arranged in a matrix form spaced apart from each other in the first direction DR1 and the second direction DR2 on a plurality of bit lines. A bottom portion of the memory vertical channel layer CH functions as a first source/drain region (not shown), an upper portion of the memory vertical channel layer CH functions as a second source/drain region (not shown), and a portion of the memory vertical channel layer CH between the first and second source/drain regions can function as a channel region (not shown).

For example, the memory vertical channel layer CH may include silicon, an oxide semiconductor, or a combination thereof, and for example, the oxide semiconductor may include InxGayZnzO (IGZO), InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, InxGayO, or a combination thereof. The memory vertical channel layer CH may include a single layer or multiple layers of the oxide semiconductor. According to some example embodiments, the memory vertical channel layer CH may have a bandgap energy greater than the bandgap energy of silicon. For example, the memory vertical channel layer CH may have a bandgap energy of about 1.5 eV to 5.6 eV. For example, a memory vertical channel layer CH may have improved (e.g., optimal) channel performance in response to having a bandgap energy of about 2.0 eV to 4.0 eV. For example, the memory vertical channel layer CH may be, but is not limited to, polycrystalline or amorphous. According to some example embodiments, the memory vertical channel layer CH may include a two-dimensional semiconductor material, for example, the two-dimensional semiconductor material may include graphene, carbon nanotubes, or a combination thereof.

The plurality of gate electrodes 611 may extend in a first direction DR1 on both sidewalls of the memory vertical channel layer CH. The plurality of gate electrodes 611 may operate as word lines of a memory cell MC.

The plurality of gate electrodes 611 may include doped polysilicon, a metal, a conductive metal nitride, a conductive metal silicide, a conductive metal oxide, or a combination thereof. For example, the plurality of gate electrodes 611 may be formed of, but are not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof.

Although not illustrated, a gate insulating layer may be further disposed surrounding the plurality of gate electrodes 611. At least a portion of the gate insulating layer may be interposed between the plurality of gate electrodes 611 and the memory vertical channel layer CH.

The capacitor contact 615 may be placed on the memory vertical channel layer CH. The capacitor contact 615 may be disposed to vertically overlap the memory vertical channel layer CH in the third direction DR3. The capacitor contact 615 may be formed of, but is not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof.

The capacitor structure CAP may include a lower electrode 617, a capacitor dielectric layer 618, and an upper electrode 619 in contact with a capacitor contact 615. The lower electrode 617 may be electrically connected to the upper surface of the capacitor contact 615. The lower electrode 617 may be arranged in a pillar type extending in the third direction DR3, but is not limited thereto. According to some example embodiments, the lower electrode 617 may be arranged to overlap the capacitor contact 615 based on the third direction DR3. Alternatively, a landing pad (not shown) may be further disposed between the capacitor contact 615 and the lower electrode 617, so that the lower electrode 617 may be arranged in a hexagonal shape.

The gate electrode 611, the memory vertical channel layer CH, and the capacitor structure CAP may be operated as one memory cell MC.

An upper bonding metal 681c, 682c may be disposed on the second metal layer 670c of the memory cell bonding area MCBA′. In the memory cell bonding area MCBA′, the upper bonding metal 681c, 682c of the cell array structure CS′ may be in contact with and electrically connected to the lower bonding metal 581c, 582c of the peripheral circuit structure PS′ by a bonding method.

The area where multiple memory cells MC and capacitor structures CAP may be arranged may be defined as a memory cell bonding area MCBA′. The bit line BL may be electrically connected to a circuit element 550c that provides a sense amplifier SA in a memory cell bonding area MCBA′ of a peripheral circuit structure PS′. For example, the bit line BL is connected to the upper bonding metal 681c, 682c in the cell array structure CS′, and the upper bonding metal 681c, 682c may be connected to the lower bonding metal 581c, 582c connected to the circuit element 550c of the sense amplifier SA. At least some of the configurations of the sense amplifier SA may be overlapped with the plurality of memory cells MC and bit lines BL based on the third direction DR3. According to some example embodiments, the sense amplifier SA may sense data that is or will be stored in a memory cell MC.

Input/output pads 504, 507 may be disposed in the external pad bonding area PA′. A lower insulating film 503 covering the lower surface of the first substrate SUB1 may be disposed on the lower portion of the first substrate SUB1, and a first input/output pad 507 may be disposed on the lower insulating film 503. The first input/output pad 507 may be connected to at least one of a plurality of circuit elements 550a, 550c disposed in the peripheral circuit structure PS′ through the first input/output contact 508.

Although not illustrated in FIG. 15, the first input/output pad 507 may be separated from the first substrate SUB1 by the lower insulating film 503, and a side insulating film is interposed between the first input/output contact 508 and the first substrate SUB1, so that the first input/output contact 508 and the first substrate SUB1 may be electrically separated.

An upper insulating film 603 covering the upper surface of the second substrate SUB2 may be disposed on the upper substrate SUB2, and a second input/output pad 504 may be placed on the upper insulating film 603. The second input/output pad 504 may be connected to at least one of a plurality of circuit elements 550a, 550c arranged in the peripheral circuit structure PS′ through the second input/output contact 661a. A first metal layer 662a and a second metal layer 670a may be sequentially stacked on top of the second input/output contact 661a. The first and second input/output contacts 661a, 508 may include a conductive material such as a metal, a metal compound, or polysilicon.

An upper bonding metal 681a, 682a may be disposed on the second metal layer 670a of the external pad bonding area PA′. In the external pad bonding area PA′, the upper bonding metal 681a, 682a of the cell array structure CS′ may be contact with and electrically connected to the lower bonding metal 581a, 582a of the peripheral circuit structure PS′ by a bonding method. Accordingly, at least one of the plurality of circuit elements 550a, 550c may be connected to the second input/output pad 504 through bonding metals 581a, 582a, 681a, 682a. The plurality of circuit elements 550a, 550c within the memory device 2000 may receive a power voltage through the second input/output pad 504.

At least some of the second input/output pads 504 may be power wire pads PWP, and at least some of the second input/output pads 504 may be exposed by the upper insulating film 603. A plurality of wires 505 separated from each other may be bonded in parallel on the second input/output pad 504. Through the second input/output pad 504, which is a power wire pad PWP, and the plurality of wires 505, the memory device 2000 can improve the impedance performance for the power voltage and improve the integrity of the received power.

The first metal layer 662a and the second input/output contact 661a overlapped under the second input/output pad 504 in a plan view may be a support structure SS for the second input/output pad 504.

The support structure SS may correspond to the support structure SS of FIGS. 10 and 11, and the support structure SS may be disposed so as not to overlap with the plurality of wires 505 in a plan view, and may surround each of the plurality of wires 505. When performing a bonding operation on a plurality of wires 505 on a second input/output pad 504, the support structure SS can firmly support the second input/output pad 504 while protecting a plurality of circuit elements 550a within the external pad bonding area PA′ through the above structure. The support structure SS can prevent or reduce in likelihood cracks from being generated in a plurality of circuit elements 550a within an external pad bonding area PA′ disposed under a second input/output pad 504 and can prevent or reduce in likelihood an interlayer insulation layer 602 disposed under the input/output pad from collapsing.

The area where bit lines BL do not overlap with may be defined as an external pad bonding area PA′. According to some example embodiments, the second substrate SUB2 or the like may not be disposed in the area where the second input/output contact 661a is placed. Additionally, the second input/output pad 504 may be arranged so as not to overlap with the bit line BL in the third direction DR3. The second input/output pad 504 may be separated from the second substrate SUB2 in a direction parallel to the upper surface of the second substrate SUB2 and may be connected to a second input/output contact 661a that penetrates the interlayer insulation layer 602 of the cell array structure CS′ in the third direction DR3.

In each of the external pad bonding area PA′ and the memory cell bonding area MCBA′ included in each of the cell array structure CS′ and the peripheral circuit structure PS′, the metal pattern of the uppermost metal layer may exist as a dummy pattern, or the uppermost metal layer may be empty.

Corresponding to the lower metal pattern disposed in the uppermost metal layer of the peripheral circuit structure PS′ in the external pad bonding area PA′, an upper metal pattern having the same shape as the lower metal pattern of the peripheral circuit structure PS′ may be disposed in the upper metal layer of the cell array structure CS′.

Additionally, in the memory cell bonding area MCBA′, an upper metal pattern 683c having the same shape as the lower metal pattern 583c may be disposed in the uppermost metal layer of the cell array structure CS′ corresponding to the lower metal pattern 583c disposed in the uppermost metal layer of the peripheral circuit structure PS′. A contact may not be disposed on the upper metal pattern 683c arranged on the uppermost metal layer of the cell array structure CS′.

While this disclosure has been described in connection with some example embodiments, it should be understood that the disclosure is not limited to the disclosed example embodiments, but, on the contrary, is intended to cover various modifications and equivalent arrangements included within the spirit and scope of the appended claims

What is claimed is:

1. A semiconductor chip comprising:
a substrate;
a wire pad on the substrate and having first and second wires separated from each other; and
a support structure between the substrate and the wire pad, the support structure including a conductive metal material, a ring region along a boundary of the wire pad in a plan view, and a center region between the first and second wires in a plan view.

2. The semiconductor chip of claim 1, wherein the wire pad overlaps the ring region and the center region in a plan view.

3. The semiconductor chip of claim 2, wherein the ring region and the center region are connected to each other and placed at a same height based on the substrate.

4. The semiconductor chip of claim 2, wherein the center region does not overlap the first and second wires in a plan view.

5. The semiconductor chip of claim 1, wherein
the wire pad includes an exposure region exposed by a passivation film,
the exposure region includes a short side extending a first length in a first direction and a long side extending a second length in a second direction intersecting the first direction, and
the second length is longer than the first length.

6. The semiconductor chip of claim 5, wherein
a ratio of the first length to the second length is 1 to x, and
the x is a real number greater than or equal to 1.6.

7. The semiconductor chip of claim 5, further comprising:
a third wire which is different from the first and second wires and is arranged on the exposure region,
wherein the first to third wires are arranged along the second direction on the exposure region.

8. The semiconductor chip of claim 1, wherein the wire pad is configured to receive power voltage.

9. The semiconductor chip of claim 1, wherein the wire pad is in contact with the support structure.

10. The semiconductor chip of claim 9, further comprising:
a wiring layer between a first surface, which is an active surface of the substrate, and the wire pad,
wherein the wiring layer includes an upper wiring line, the upper wiring line being an uppermost wiring line of a plurality of wiring lines within the wiring layer relative to the first surface, and
the support structure is included in the upper wiring line.

11. The semiconductor chip of claim 1, wherein the support structure further includes a plurality of contacts between the wire pad and the center region and between the wire pad and the ring region.

12. The semiconductor chip of claim 11, further comprising:
a wiring layer on a first surface, the first surface is an active surface of the substrate,
wherein the wiring layer includes a lower wiring line, the lower wiring line being a lowermost wiring line of a plurality of wiring lines within the wiring layer relative to the first surface,
the wire pad is on a second surface of the substrate opposite to the first surface, and
the support structure is included in the lower wiring line.

13. A semiconductor chip comprising:
a substrate;
a first wire pad on the substrate and configured to receive a power voltage;
a second wire pad non-overlapping with the first wire pad on the substrate in a plan view and configured to receive a data signal; and
a support structure between the substrate and the first wire pad, the support structure including a conductive metal material, a ring region along a boundary of the first wire pad in a plan view, and a center region extending in a first direction within the ring region.

14. The semiconductor chip of claim 13, further comprising:
a first wire and a second wire separated from each other and on the first wire pad,
wherein the center region is between the first and second wire in a plan view.

15. The semiconductor chip of claim 14, wherein the center region does not overlap with the first and second wires in a plan view.

16. A semiconductor package comprising:
a package substrate including a substrate wire pad; and
a first semiconductor chip including a chip wire pad on the package substrate and connected to the substrate wire pad through a first and second wire, the first semiconductor chip including a support structure including a ring region along a boundary of the chip wire pad in a plan view and a center region between the first and second wires in a plan view.

17. The semiconductor package of claim 16, wherein
the support structure includes a conductive material, and
the chip wire pad overlaps with the ring region and the center region in a plan view.

18. The semiconductor package of claim 16, further comprising:
a second semiconductor chip stacked with the first semiconductor chip on the package substrate,
wherein the first semiconductor chip includes a first substrate, a first wiring layer on a first surface, the first surface is an active surface of the first substrate, and a first bonding pad on the first wiring layer,
the second semiconductor chip includes a second substrate, a second wiring layer on a second surface, the second surface is an active surface of the second substrate, and a second bonding pad on the second wiring layer and in contact with the first bonding pad, and
the chip wire pad is on a third surface of the first substrate opposite the second surface.

19. The semiconductor package of claim 18, wherein the support structure further includes a plurality of contacts between the chip wire pad and the center region and between the chip wire pad and the ring region.

20. The semiconductor package of claim 19, wherein the first semiconductor chip further includes a memory cell array non-overlapping with the plurality of contacts on the first surface in a plan view and configured to store data.
